(19) United States
(12) Patent Application Publication
(10) Pub. No.: US 2022/0238330 A1
(43) Pub. Date: Jul. 28, 2022

(54) HIGH THROUGHPUT DEPOSITION PROCESS

(71) Applicant: ENTEGRIS, INC., Billerica, MA (US)

(72) Inventors: Philip S.H. CHEN, Bethel, CT (US); Eric Condo, Shelton, CT (US); David Kuiper, Brookfield, CT (US); Thomas H. Baum, New Fairfield, CT (US); Susan V. Dimeo, New City, NY (US)

(21) Appl. No.: 17/579,487

(22) Filed: Jan. 19, 2022

Related U.S. Application Data
(60) Provisional application No. 63/141,824, filed on Jan. 26, 2021.

(51) Int. Cl. H01L 21/02; C23C 16/455; C23C 16/36; C23C 16/30; C07F 7/10

(52) U.S. Cl. CPC H01L 21/02126; C23C 16/45536; C23C 16/36; C07F 7/10; H01L 21/02216; H01L 21/02274; H01L 21/0228; C23C 16/308

(57) ABSTRACT

The invention provides a PEALD process to deposit etch resistant SiOCN films. These films provide improved growth rate, improved step coverage and excellent etch resistance to wet etchants and post-deposition plasma treatments containing O₂ co-reactant. In one embodiment, this PEALD process relies on a single precursor—a bis(dialkylamino)tetraalkyldisiloxane, together with hydrogen plasma to deposit the etch-resistant thin-films of SiOCN. Since the film can be deposited with a single precursor, the overall process exhibits improved throughput.

### TECHNICAL FIELD

In general, the invention relates to materials and processes for depositing thin films of silicon oxycarbonitride (SiOCN) onto microelectronic device surfaces. These films serve as low dielectric constant insulators with excellent wet and dry etching resistance and ashing resistance.

### BACKGROUND

Silicon nitride (SiN) has been used for source and drain spacer (S/D spacer) for a fin field-effect transistor (FinFET) and gate-all-around (GAA) structure due to its high wet etch and oxygen (O₂) ashing resistance. Unfortunately, SiN has a high dielectric constant (k) of about 7.5. Carbon and nitrogen doped silicon dioxide (SiO₂) SiOCN spacers have been developed to reduce the dielectric constant and maintain excellent etch and ashing resistance. Currently, the best etch and ashing resistant SiOCN dielectrics have a k value of around 4.0. Etch and ashing resistant dielectrics with a k value of <3.5 are needed for next generation devices.

Additionally, there remains a need for improved organosilicon precursors for formation of silicon-containing films in the manufacture of microelectronic devices, particularly in processes utilizing low temperature vapor deposition techniques utilized for the formation of SiOCN films. In particular, there is a need for liquid silicon precursors with good thermal stability, high volatility, and reactivity with a substrate surface.

Increasing device performance requires new materials to enhance the ability to isolate both transistors and interconnect circuits. These films often require low dielectric constant properties (i.e., <4), while also enduring subsequent processing steps during the device fabrication, including wet-etch and dry-etch resistance. Further, the deposited insulators must not change when exposed to post-deposition processing. When these films are deposited in the front-end-of-line, the films must conformally coat 3D structures, as found in in FinFET devices, while demonstrating uniform dielectric properties over the entire structure. Since the film remains in the device, electrical performance cannot change with post-deposition processing. Plasma-based deposition processes often result in films with non-uniform electrical properties, wherein the top of the film is altered by enhanced plasma bombardment. Concurrently, the sidewalls of the 3D structure, coated with the same film, may display different properties, a result of reduced electron bombardment during deposition. Nonetheless, the film must withstand wet-etching and/or post-plasma processing in oxidizing or reducing environments.

### SUMMARY OF THE INVENTION

The invention provides a plasma enhanced atomic layer deposition (PEALD) process to deposit etch resistant SiOCN films. These films provide improved growth rate, improved step coverage and improved etch resistance to wet etchants and post-deposition plasma treatments containing O₂ co-reactant. This PEALD process relies on a single precursor, for example a bis(dialkylamino)tetraalkyldisiloxane, together with hydrogen plasma to deposit the etch-resistant thin-films of SiOCN. Since the film can be deposited with a single precursor, the overall process exhibits improved throughput. The films display resistance to wet etching with dilute aqueous hydrofluoric acid (HF) solutions, both after deposition and after post-deposition plasma treatment(s). Accordingly, these films are expected to display excellent stability towards post-deposition fabrication steps utilized during device manufacturing and build. (Reference FIGS. 2 and 3).

In a first aspect, the invention provides a process for the vapor deposition of a SiOCN film onto a microelectronic device surface, which comprises introducing into said reaction zone reactants chosen from:
a. at least one compound of the formula

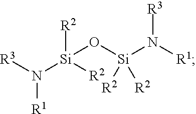

b. wherein each R¹ is independently chosen from hydrogen and C₁-C₄ alkyl, each R² is independently chosen from hydrogen and C₁-C₄ alkyl; and each R³ is chosen from hydrogen and C₁-C₄ alkyl, provided that when R³ is hydrogen, R¹ is C₁-C₄ alkyl; and a reducing gas in plasma form or an oxidizing gas, with purging of each reactant prior to exposing the film to the next reactant.

### BRIEF DESCRIPTION OF THE DRAWINGS

The disclosure may be more completely understood in consideration of the following description of various illustrative embodiments in connection with the accompanying drawings

FIG. 1 is a plot of SiOCN thickness in angstroms versus numbers of PEALD cycles. This data was generated using bis(diethylamino)tetramethyldisiloxane, using atomic layer deposition (ALD) conditions of 265° C., a 2 second pulse of the silicon precursor, followed by a 5 second pulse of hydrogen plasma at 250 watts. The process resulted in a film formation of about 0.2 Å per cycle.

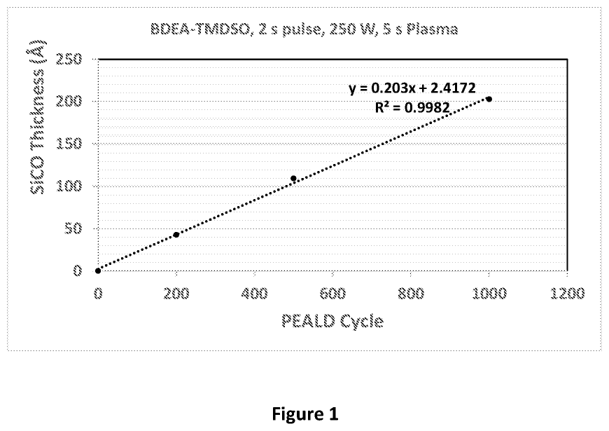

FIG. 2 is a plot of oxide thickness versus etch time, illustrating a wet etch resistance (WER) of less than 0.1 Å per minute with 50:1 dilute hydrofluoric acid (DHF). The SiOCN film of the invention is compared to thermal oxide.

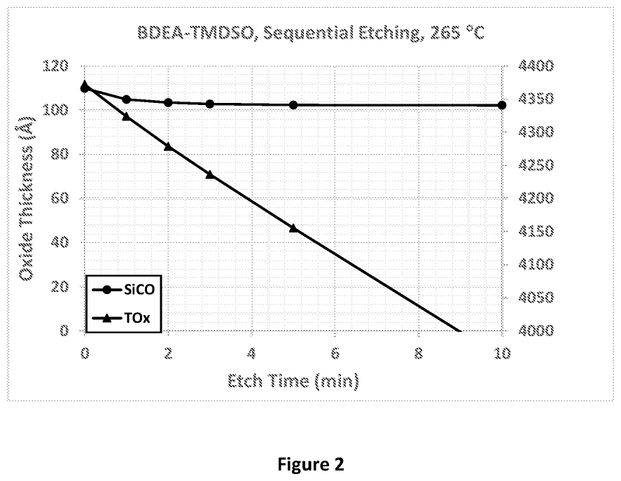

FIG. 3 is a plot of etch depth difference, comparing the SiOCN film of the invention as deposited versus the etch depth after exposure to ashing plasma power ranging from 100 to 400 watts. This data illustrates an ashing depth of about 7 Å per minute at 100 watts. This data illustrates a comparable ashing resistance compared to SiN.

FIG. 4 is a XPS plot of the atomic percentages of constituent atoms for the SiOCN film of Example 1 at varying depths of the film. At the bulk of the film, the composition is as follows: 16.6 atomic percentage carbon, 19.3 atomic percentage nitrogen, 24.7 atomic percentage of oxygen, and 39.4 atomic percentage of silicon.

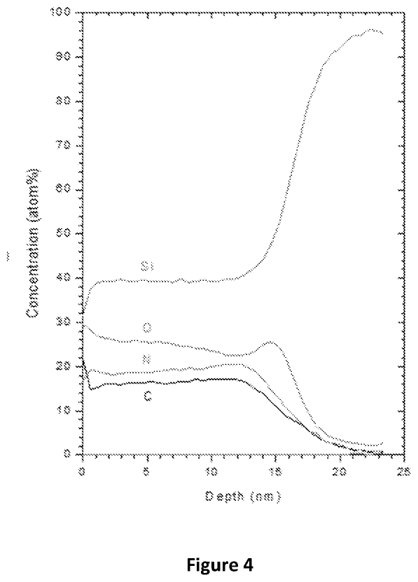

### DETAILED DESCRIPTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The term “about” generally refers to a range of numbers that is considered equivalent to the recited value (e.g., having the same function or result). In many instances, the term “about” may include numbers that are rounded to the nearest significant figure.

Numerical ranges expressed using endpoints include all numbers subsumed within that range (e.g., 1 to 5 includes 1, 1.5, 2, 2.75, 3, 3.80, 4 and 5).

In a first aspect, the invention provides a process for the vapor deposition of a SiOCN film onto a microelectronic device surface in a reaction zone, which comprises introducing into said reaction zone reactants chosen from:
a. at least one compound of the formula

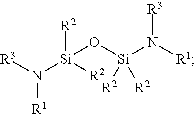

wherein each R¹ is independently chosen from hydrogen and C₁-C₄ alkyl, each R² is independently chosen from hydrogen and C₁-C₄ alkyl; and each R³ is chosen from hydrogen and C₁-C₄ alkyl, provided that when R³ is hydrogen, R¹ is C₁-C₄ alkyl; and
b. a reducing gas in plasma form or an oxidizing gas, with purging of each reactant prior to exposing the film to the next reactant.

In the process steps above, a. and b. represent a pulse sequence comprising one cycle; this cycle can be repeated until the deposited film has reached a desired thickness.

In this process, the compounds of formula (I) include those where R¹ is chosen from hydrogen, methyl, ethyl, propyl, isopropyl, n-butyl, isobutyl, sec-butyl, and t-butyl, R² is chosen from hydrogen, methyl, ethyl, propyl, isopropyl, n-butyl, isobutyl, sec-butyl, and t-butyl, and R³ is chosen from hydrogen, methyl, ethyl, propyl, isopropyl, n-butyl, isobutyl, sec-butyl, and t-butyl. In this process, when R³ is hydrogen, R¹ is C₁-C₄ alkyl. In one embodiment, each R¹ and each R³ is ethyl and each R² is methyl, i.e., a compound of the formula:

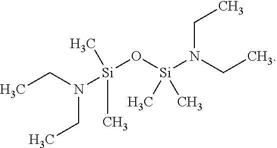 [SMILES: CCN(CC)[Si](C)(C)O[Si](C)(C)N(CC)CC]

As used herein, the term “SiOCN” film refers to films containing varying proportions of silicon, oxygen, carbon, and nitrogen. In one embodiment, the invention provides a film having from about

(i) 30 to 50 atomic percentage of silicon;

(ii) 5 to 30 atomic percentage of nitrogen;

(iii) 2 to 25 atomic percentage of carbon; and

(iv) 20 to 40 atomic percentage of oxygen.

In another embodiment, the invention provides a film having about

(i) 25 to 45 atomic percentage of silicon;

(ii) 10 to 25 atomic percentage of nitrogen;

(iii) 5 to 20 atomic percentage of carbon; and

(iv) 25 to 35 atomic percentage of oxygen.

In certain embodiments, the SiOCN films of the invention have about 15 to about 20 atomic percentage of nitrogen and in other embodiments, about 8 to about 18 atomic percentage of carbon.

In general, the compounds of formula (I) can be prepared by treatment of the corresponding halodisiloxane with a primary or secondary amine.

The compounds above can be employed for forming high-purity thin silicon-containing films by any suitable ALD technique, and pulsed plasma processes. Such vapor deposition processes can be utilized to form silicon-containing films on microelectronic devices by utilizing deposition temperatures of from about 200° C. to about 550° C. to form films having a thickness of from about 20 angstroms to about 200 angstroms.

In the process of the invention, the compounds of formula (I) may be reacted with the desired microelectronic device substrate in any suitable manner, for example, in a single wafer chamber, or in a furnace containing multiple wafers.

Alternately, the process of the invention can be conducted as an ALD-like process. As used herein, the terms “ALD or ALD-like” refers to processes where each reactant is introduced sequentially into a reactor such as a single wafer ALD reactor, semi-batch ALD reactor, or batch furnace ALD reactor, or each reactant is exposed to the substrate or microelectronic device surface by moving or rotating the substrate to different sections of the reactor and each section is separated by an inert gas curtain, i.e., spatial ALD reactor or roll-to roll ALD reactor.

In one embodiment, the invention relates to PEALD for depositing SiOCN films using the compounds of formula (I), together with a reducing gas in plasma form. Nitrogen plasma may be useful for the formation of films having higher nitrogen atomic percentages while utilizing the compounds of formula (I) and reducing gas in plasma form as taught herein. Accordingly, in another aspect, the invention provides a process for the vapor deposition of a SiOCN film onto a microelectronic device surface in a reaction zone, which comprises sequentially introducing into said reaction zone reactants chosen from:
a. at least one compound of the formula

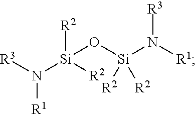

wherein each R¹ is independently chosen from hydrogen and C₁-C₄ alkyl, each R² is independently chosen from hydrogen and C₁-C₄ alkyl; and each R³ is chosen from hydrogen and C₁-C₄ alkyl, provided that when R³ is hydrogen, R¹ is C₁-C₄ alkyl; and
b. a reducing gas in plasma form, with purging of each reactant prior to exposing the film to the next reactant.

As used herein, the term “reducing gas in plasma form”, means the reducing gas in plasma form is comprised of gases chosen from hydrogen (H₂), hydrazine (N₂H₄); C₁-C₄ alkyl hydrazines, such as methyl hydrazine, t-butyl hydrazine, 1,1-dimethylhydrazine, and 1,2-dimethylhydrazine, which are utilized in combination with a plasma formed from an inert gas, such as N₂, helium or argon alone or in combination with H₂. For example, a continuous flow of inert gas such as argon is utilized while a radio frequency field (R_{f}) field is initiated, followed by initiation of hydrogen to provide the plasma H₂. Typically, the plasma power utilized ranges from about 50 to 500 Watts at 13.6 MHz.

Similarly, oxidizing gases may be utilized in various cycles of the film deposition in order to increase the oxygen content of the film and to lower the carbon content. Suitable oxidizing gases include O₂, O₂ plasma, ozone (O₃), water (H₂O), and nitrous oxide (N₂O). The embodiments utilizing an oxidizing gas pulse may be used in sequence(s) with the use of a reducing gas in other pulse sequences.

In certain embodiments, the pulse time (i.e., duration of exposure to the substrate) for the reactants depicted above (i.e., the compound(s) of formula (I) and reducing gas in plasma form) ranges between about 1 and 10 seconds. When a purge step is utilized, the duration is from about 1 to 10 seconds or 2 to 5 seconds. In other embodiments, the pulse time for each reactant ranges from about 2 to about 5 seconds.

The process disclosed herein involves one or more purge gases. The purge gas, which is used to purge away unconsumed reactants and/or reaction by-products, is an inert gas that does not react with the precursors. Exemplary purge gases include, but are not limited to, argon, nitrogen, helium, neon, hydrogen, and mixtures thereof. In certain embodiments, a purge gas such as Ar is supplied into the reactor at a flow rate ranging from about 10 to about 2000 sccm for about 0.1 to 1000 seconds, thereby purging the unreacted material and any by-product that may remain in the reactor.

The respective step of supplying the compound(s) of formula (I), reducing gas in plasma form, and/or other precursors, source gases, and/or reagents may be performed by changing the sequences for supplying them and/or changing the stoichiometric composition of the resulting dielectric film.

In the process of the invention, energy is applied to the various reactants to induce reaction and to form the SiOCN film on the microelectronic device substrate. Such energy can be provided by, but not limited to, thermal, pulsed thermal, plasma, pulsed plasma, high density plasma, inductively coupled plasma, remote plasma process, and combinations thereof. In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively, a remote plasma-generated process in which plasma is generated ‘remotely’ of the reaction zone and substrate, being supplied into the reactor.

As used herein, the term “microelectronic device” corresponds to semiconductor substrates, including a type of non-volatile flash memory in which the memory cells are stacked vertically in multiple layers (3D NAND) structures, flat panel displays, and microelectromechanical systems (MEMS), manufactured for use in microelectronic, integrated circuit, or computer chip applications. It is to be understood that the term “microelectronic device” is not meant to be limiting in any way and includes any substrate that includes a negative channel metal oxide semiconductor (nMOS) and/or a positive channel metal oxide semiconductor (pMOS) transistor and will eventually become a microelectronic device or microelectronic assembly. Such microelectronic devices contain at least one substrate, which can be chosen from, for example, silicon, SiO₂, Si₃N₄, OSG, FSG, silicon carbide, hydrogenated silicon carbide, silicon nitride, hydrogenated silicon nitride, silicon carbonitride, hydrogenated silicon carbonitride, boronitride, antireflective coatings, photoresists, germanium, germanium-containing, boron-containing, Ga/As, a flexible substrate, porous inorganic materials, metals such as copper and aluminum, and diffusion barrier layers such as but not limited to TiN, Ti(C)N, TaN, Ta(C)N, Ta, W, or WN. The films are compatible with a variety of subsequent processing steps such as, for example, chemical mechanical planarization (CMP) and anisotropic etching processes.

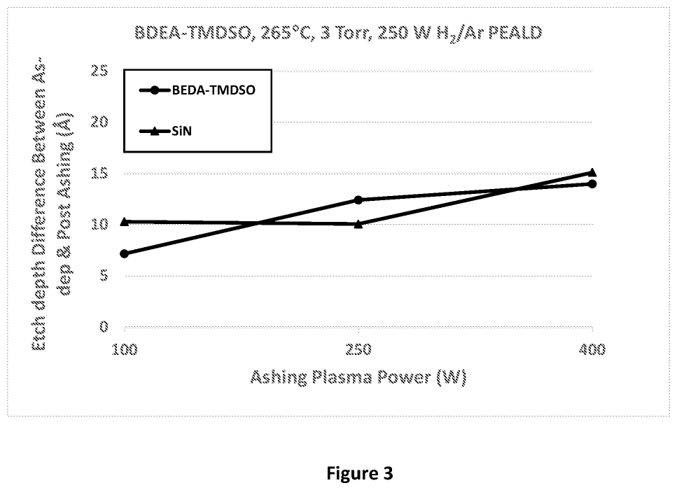

These films provide low etch resistance to wet etchants and O₂ plasmas. O₂ plasma ashing processes were carried out at 340° C. and 3 Torr pressure for 1 minute with 500 sccm O₂ flow and plasma powers of 100, 250 and 400 W. In this regard, with reference to FIG. 3, the invention provides in another aspect a SiOCN film which exhibits an ashing damage difference of only about 2.5 angstroms over a silicon nitride reference sample when exposed to oxygen plasma at 250 Watts for 60 seconds.

As noted above, in certain embodiments, the SiOCN films of the invention have about 15 to about 25 atomic percentage of nitrogen and about 16 atomic percentage of carbon. Utilizing the process of the invention such SiOCN films having a dielectric constant (k) of less than about 5 can be prepared.

In general, the desired thickness of the SiOCN films thus prepared are about 20 Å to about 200 Å.

Doping of the low-k SiCO films with nitrogen, via the interaction between the formula (I) precursors, and subsequent reaction with H₂ plasma, dramatically improves the wet etch and O₂ plasma ashing resistance of the resulting SiOCN films.

In the process of the invention, the delivery rate of the formula (I) precursor may be about 10 to 50 mg per PEALD cycle.

In another aspect, the invention provides compounds of the formula

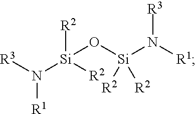

wherein each R¹ is independently chosen from hydrogen and C₁-C₄ alkyl, each R² is independently chosen from hydrogen and C₁-C₄ alkyl; and each R³ is chosen from hydrogen and C₁-C₄ alkyl, provided that when R³ is hydrogen, R¹ is C₁-C₄ alkyl.

Such compounds are useful as precursors in the deposition of silicon-containing films. In one embodiment, each R¹ is ethyl, each R² is methyl, and each R³ is ethyl. In another embodiment, each R¹ is isopropyl, each R³ is hydrogen, and each R² is methyl.

This invention can be further illustrated by the following examples of certain embodiments thereof, although it will be understood that these examples are included merely for purposes of illustration and are not intended to limit the scope of the invention unless otherwise specifically indicated.

### Example 1—Deposition using Bis(diethylamino)tetramethyldisiloxane as Sole Precursor

The PEALD SiCON deposition was conducted using a PEALD system, with a susceptor temperature of 300° C., a showerhead temperature of 170° C., a chamber pressure of 3 Torr, and an ambient inert gas flow of 500 sccm. The coupon temperature during deposition was approximately 265° C.

H2 plasma was created using a direct plasma system which creates a plasma between the showerhead and the susceptor/wafer. Plasma powers was fixed at 250 W, and the plasma pulse times was fixed at 5 seconds.

The pulsing scheme for PEALD of SiOCN consisted of the following:

1. Precursor pulse [bis(diethylamino)tetramethyldisiloxane] for 2 sec

2. Inert gas purge for 5 sec

3. H₂ Plasma pulse for 5 sec

4. Inert gas purge for 5 sec

### Example 2—Synthesis of 1,3-Bis(diethylamido)tetramethyldisiloxane

To a 4-neck 5 L round bottom flask equipped with a mechanical stirrer, thermocouple, gas/vacuum inlet adapter, and condenser with a tubing inlet was added 400 mL (3.87 mol, 4.4 eq) diethylamine and 3 L of anhydrous diethyl ether. A 1 L flask with a gas/vacuum inlet valve was charged with 173 mL (0.885 moles, 1.0 eq) 1,3-dichlorotetramethyldisiloxane in 600 mL anhydrous hexanes. Both flasks were cooled in a brine bath to about −5° C. then connected with PTFE tubing. The 1,3-dichlorotetramethyldisiloxane solution was added in portions to the stirred amine solution such that the internal temperature was maintained below 0° C. When the addition was complete, the reaction mixture was allowed to warm slowly to ambient temperature and stir for 48 hours. The reaction mixture, which contained copious amounts of diethylamine hydrochloride salts, was filtered under an inert atmosphere into a 5 L flask, and the salts were washed with 2×1.5 L aliquots of anhydrous diethyl ether. The solvent was removed from the filtrates in-vacuo and the resulting clear yellow oil (230.7 g) was distilled in a short path distillation head at 100 mtorr pressure to give 156.5 g product (64% yield, >98% pure). ¹H NMR (d₆-benzene): d 2.85 (q, 2H), 1.09 (t, 3H), 0.19 (s, 2H). ¹³C NMR (d₆-benzene): d 40.5, 16.7, 0.7. ²⁹Si NMR (d₆-benzene) −13.4.

### Example 3—Synthesis of 1,3-Bis(isopropylamido)tetramethyldisiloxane

To a 4-neck 5 L round bottom flask equipped with a mechanical stirrer, thermocouple, gas/vacuum inlet adapter, and condenser with a tubing inlet was added isopropylamine (4.4 eq) and 3 L of anhydrous diethyl ether. A 1 L flask with a gas/vacuum inlet valve was charged with 173 mL (0.885 moles, 1.0 eq) 1,3-dichlorotetramethyldisiloxane in 600 mL anhydrous hexanes. Both flasks were cooled in a brine bath to about −5° C. then connected with PTFE tubing. The 1,3-dichlorotetramethyldisiloxane solution was added in portions to the stirred amine solution such that the internal temperature was maintained below 0° C. When the addition was complete, the reaction mixture was allowed to warm slowly to ambient temperature and stir for 48 hours. The reaction mixture, which contained copious amounts of isopropylamine hydrochloride salts, was filtered under an inert atmosphere into a 5 L flask, and the salts were washed with 2×1.5 L aliquots of anhydrous diethyl ether. The solvent was removed from the filtrates in-vacuo and the resulting clear yellow oil was obtained. This oil was purified by subsequent vacuum distillation.

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respects, only illustrative. The disclosure's scope is, of course, defined in the language in which the appended claims are expressed.

What is claimed is:

1. A process for the vapor deposition of a silicon oxycarbonitride film onto a microelectronic device surface, which comprises introducing into a reaction zone the following reactant chosen from:
a. at least one compound of the formula 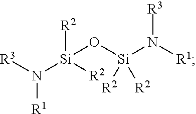
wherein each R¹ is independently chosen from hydrogen and C₁-C₄ alkyl, each R² is independently chosen from hydrogen and C₁-C₄ alkyl; and each R³ is chosen from hydrogen and C₁-C₄ alkyl, provided that when R³ is hydrogen, R¹ is C₁-C₄ alkyl; and
b. a reducing gas in plasma form or an oxidizing gas, with purging of each reactant prior to exposing the film to the next reactant.

2. The process of claim 1, wherein each R¹ is ethyl.

3. The process of claim 1, wherein each R² is methyl.

4. The process of claim 1, wherein the reducing gas is chosen from hydrogen, hydrazine; methyl hydrazine, t-butyl hydrazine, 1,1-dimethylhydrazine, and 1,2-dimethylhydrazine.

5. The process of claim 4, wherein the reducing gas is hydrogen.

6. The process of claim 1, wherein the oxidizing gas is chosen from oxygen, oxygen plasma, ozone, water, and nitrous oxide.

7. The process of claim 1, further comprising repeating a. and b. until a film of a desired thickness has been obtained.

8. A process for the vapor deposition of a silicon oxycarbonitride film onto a microelectronic device surface, which comprises introducing into a reaction zone the following reactants chosen from:
a. at least one compound of the formula 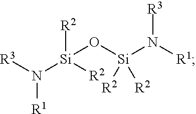
wherein each R¹ is independently chosen from hydrogen and C₁-C₄ alkyl, each R² is independently chosen from hydrogen and C₁-C₄ alkyl; and each R³ is chosen from hydrogen and C₁-C₄ alkyl, provided that when R³ is hydrogen, R¹ is C₁-C₄ alkyl; and
b. a reducing gas in plasma form, with purging of each reactant prior to exposing the film to the next reactant.

9. The process of claim 8, wherein each R¹ is ethyl.

10. The process of claim 8, wherein each R² is methyl.

11. The process of claim 7, wherein the reducing gas is chosen from hydrogen, hydrazine; methyl hydrazine, t-butyl hydrazine, 1,1-dimethylhydrazine, and 1,2-dimethylhydrazine.

12. The process of claim 11, wherein the reducing gas is hydrogen.

13. The process of claim 11, further comprising repeating a. and b. until a film of a desired thickness has been obtained.

14. The process of claim 13, wherein the silicon oxycarbonitride film so formed exhibits an ashing damage difference as low as about 2.5 angstroms over a silicon nitride reference sample when exposed to oxygen plasma at 250 Watts for 60 seconds.

15. A compound of the formula 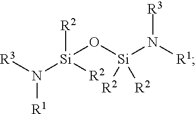
wherein each R¹ is independently chosen from hydrogen and C₁-C₄ alkyl, each R² is independently chosen from hydrogen and C₁-C₄ alkyl; and each R³ is chosen from hydrogen and C₁-C₄ alkyl, provided that when R³ is hydrogen, R¹ is C₁-C₄ alkyl.

16. The compound of claim 15, wherein each R¹ is ethyl, each R² is methyl, and each R³ is ethyl.

17. The compound of claim 15, wherein each R¹ is isopropyl, each R³ is hydrogen, and each R² is methyl.
